(19) United States
(12) Patent Application Publication
(10) Pub. No.: US 2006/0145298 A1
(43) Pub. Date: Jul. 6, 2006

(54) Semiconductor device

(75) Inventor: Ichiro Omura, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/296,312

(22) Filed: Dec. 8, 2005

(30) Foreign Application Priority Data
Dec. 9, 2004 (JP) 2004-356980

(51) Int. Cl. H01L 29/00

(52) U.S. Cl. 257/547

(57) ABSTRACT

According to the present invention, there is provided a semiconductor device including a MOSFET, comprising: a second-conductivity-type semiconductor layer selectively formed in one surface portion of a first first-conductivity-type semiconductor layer; a second first-conductivity-type semiconductor layer selectively formed in a surface portion of said second-conductivity-type semiconductor layer; a first main electrode electrically connected to said second first-conductivity-type semiconductor layer and second-conductivity-type semiconductor layer; a second main electrode electrically connected to the other surface of said first first-conductivity-type semiconductor layer; and a control electrode formed on the surfaces of said second first-conductivity-type semiconductor layer, second-conductivity-type semiconductor layer, and first first-conductivity-type semiconductor layer via an insulating film, and a junction between said second main electrode and first first-conductivity-type semiconductor layer is a Schottky contact.

### CROSS REFERENCE TO RELATED APPLICATION

This application is based upon and claims benefit of priority under 35 USC §119 from the Japanese Patent Application No. 2004-356980, filed on Dec. 9, 2004, the entire contents of which are incorporated herein by reference.

### BACKGROUND OF THE INVENTION

The present invention relates to a semiconductor device.

MOSFETs are widely used in power supply circuits.

FIG. 17 shows the circuit configuration of a unidirectional insulated DC-DC converter using conventional MOSFETs.

A capacitance element C100, a series circuit of a switching element M101 and diode D101, and a series circuit of a diode D102 and switching element M102 are connected in parallel between input terminals IN101 and IN102. The primary side of a transformer T101 is connected to the connecting point of the switching element M101 and diode D101 and the connecting point of the diode D102 and switching element M102. A diode D111 and inductance element L111 are connected in series between one secondary side of the transformer T101 and an output terminal OUT100. The other secondary side of the transformer T101 is connected to an output terminal OUT101. A diode D112 is connected to the output terminal OUT101 and the connecting point of the diode D111 and inductance element L111.

This circuit has a bridge arrangement, and an electric current I100 flows in a direction indicated by the arrow when the switching elements M101 and M102 are turned on. Accordingly, when the two switching elements M101 and M102 are turned on, the electric current I100 gradually increases. When the electric current I100 has reached a maximum value, the two switching elements M101 and M102 are turned off. Since this turns off the electric current I100, the electric current I100 gradually reduces. Consequently, the electric current I100 having the shape of a triangular wave flows to the primary side of the transformer T100.

As described above, the conventional circuit configuration is not an inverter bridge circuit capable of bidirectionally transmitting energy, i.e., the energy flows only from the primary side to the secondary side of the transformer T100.

The following references disclose the conventional DC-DC converters.

Reference 1: U.S. Pat. No. 5,915,179

Reference 2: U.S. Pat. No. 5,693,569

Reference 3: U.S. Pat. No. 5,614,749

It is conventionally impossible to form a bidirectional DC-DC converter by using MOSFETs for the following reasons.

When a MOSFET is turned on, an electric current flows from the drain to the source. An inverter operation has a mode in which energy from a load flows to a power supply through a diode. In this mode, even when a diode for preventing a reverse electric current is connected in parallel between the drain and source of the MOSFET, a body diode formed by a P-type base, N-type drift, and N-type substrate operate in the MOSFET. When the threshold voltage of a body diode of the MOSFET is, e.g., about 0.8 V, this diode is forward-biased and turned on if the drain potential becomes lower by about 0.8 V or more than the source potential.

Since the body diode is a bipolar operating element, it cannot operate at high speed. This makes it impossible to raise the speed of the switching operation of the inverter.

Even when a high-speed element such as a Schottky barrier diode using silicon carbide (to be referred to as SiC hereinafter) is used as a diode, the silicon body diode parasitic on the MOSFET has a large number of stored carriers, and hence cannot operate at high speed.

When an IGBT (Insulated Gate Bipolar Transistor) is used as a switching element, no reverse electric current flows through this IGBT, so no body diode operates unlike in the MOSFET.

Since, however, the IGBT itself is a bipolar element, its operating speed is lower than that of the MOSFET formed on a silicon substrate. This also makes it impossible to provide a bidirectional DC-DC converter capable of switching at high speed.

Especially when a unipolar high-speed diode such as a Schottky barrier diode using SiC appears, high speed operation of a switching element is required. However, it cannot be achieved because of a low speed of a body diode of the MOSFET, even if a Schottky barrier diode using silicon carbide operates at high speed.

### SUMMARY OF THE INVENTION

According to one aspect of the present invention, there is provided a semiconductor device including a MOSFET, said MOSFET comprising:

a second-conductivity-type semiconductor layer selectively formed in one surface portion of a first first-conductivity-type semiconductor layer;

a second first-conductivity-type semiconductor layer selectively formed in a surface portion of said second-conductivity-type semiconductor layer;

a first main electrode electrically connected to said second first-conductivity-type semiconductor layer and second-conductivity-type semiconductor layer;

a second main electrode electrically connected to the other surface of said first first-conductivity-type semiconductor layer; and

a control electrode formed on the surfaces of said second first-conductivity-type semiconductor layer, second-conductivity-type semiconductor layer, and first first-conductivity-type semiconductor layer via an insulating film, and

a junction between said second main electrode and first first-conductivity-type semiconductor layer is a Schottky contact.

According to one aspect of the present invention, there is provided a semiconductor device including a MOSFET, said MOSFET comprising:

a first second-conductivity-type semiconductor layer selectively formed in one surface portion of a first first-conductivity-type semiconductor layer formed in one surface portion of a first-conductivity-type semiconductor substrate;

a second first-conductivity-type semiconductor layer formed selectively in a surface portion of said second-conductivity-type semiconductor layer;

a first main electrode electrically connected to said second first-conductivity-type semiconductor layer and first second-conductivity-type semiconductor layer;

a third first-conductivity-type semiconductor layer or second second-conductivity-type semiconductor layer formed in the other surface portion of said first-conductivity-type semiconductor substrate, and having an impurity concentration lower than that of said first-conductivity-type semiconductor substrate;

a second main electrode electrically connected to said third first-conductivity-type semiconductor layer or second second-conductivity-type semiconductor layer; and

a control electrode formed on the surfaces of said second first-conductivity-type semiconductor layer, first second-conductivity-type semiconductor layer, and first first-conductivity-type semiconductor layer via an insulating film, and

a junction between said second main electrode and first first-conductivity-type semiconductor layer is a Schottky contact.

According to one aspect of the present invention, there is provided a semiconductor device, comprising:

a MOSFET having,

a second-conductivity-type semiconductor layer selectively formed in one surface portion of a first first-conductivity-type semiconductor layer,

a second first-conductivity-type semiconductor layer selectively formed in a surface portion of said second-conductivity-type semiconductor layer,

a first main electrode electrically connected to said second first-conductivity-type semiconductor layer and second-conductivity-type semiconductor layer, and connected to a source terminal,

a second main electrode electrically connected to the other surface of said first first-conductivity-type semiconductor layer, and

a control electrode formed on the surfaces of said second first-conductivity-type semiconductor layer, second-conductivity-type semiconductor layer, and first first-conductivity-type semiconductor layer via an insulating film, and

a diode having a cathode connected to said second main electrode, and an anode connected to a drain terminal.

### BRIEF DESCRIPTION OF THE DRAWINGS

FIG. 1 is a circuit diagram showing the arrangement of a DC-DC converter according to the first embodiment of the present invention;

FIG. 2 is a circuit diagram showing the arrangement of MOSFETs usable as switching elements and diodes in the DC-DC converter shown in FIG. 1;

FIG. 3 is a circuit diagram showing the arrangement of MOSFETs usable as switching elements and diodes in the DC-DC converter shown in FIG. 1;

FIG. 4 is a longitudinal sectional view showing the operation state of the MOSFET when it is ON;

FIG. 5 is a view showing the potential in the operation state shown in FIG. 4;

FIG. 6 is a longitudinal sectional view showing the operation state of the MOSFET when it is OFF;

FIG. 7 is a view showing the potential in the operation state shown in FIG. 6;

FIG. 8 is a longitudinal sectional view showing the operation state of the MOSFET when a reverse bias is applied to it;

FIG. 9 is a view showing the potential in the operation state shown in FIG. 8;

FIG. 10 is a longitudinal sectional view showing an example of the structure of a MOSFET usable as a switching element in a DC-DC converter according to the second embodiment of the present invention;

FIG. 11 is a longitudinal sectional view showing an example of the structure of a MOSFET usable as a switching element in a DC-DC converter according to the third embodiment of the present invention;

FIG. 12 is a longitudinal sectional view showing an example of the structure of a MOSFET usable as a switching element in a DC-DC converter according to the fourth embodiment of the present invention;

FIG. 13 is a longitudinal sectional view showing an example of the package structure of a MOSFET usable as a switching element and a diode in the DC-DC converter according to any one of the first to fourth embodiments;

FIG. 14 is a longitudinal sectional view showing another example of the package structure of a MOSFET usable as a switching element and a diode in the DC-DC converter according to any one of the first to fourth embodiments;

FIG. 15 is a longitudinal sectional view showing another example of the package structure of a MOSFET usable as a switching element and a diode in the DC-DC converter according to any one of the first to fourth embodiments;

FIG. 16 is a longitudinal sectional view showing another example of the package structure of a MOSFET usable as a switching element and a diode in the DC-DC converter according to any one of the first to fourth embodiments;

FIG. 17 is a circuit diagram showing the arrangement of a conventional DC-DC converter.

### DETAILED DESCRIPTION OF THE INVENTION

Embodiments of the present invention will be described below with reference to the accompanying drawings.

### First Embodiment

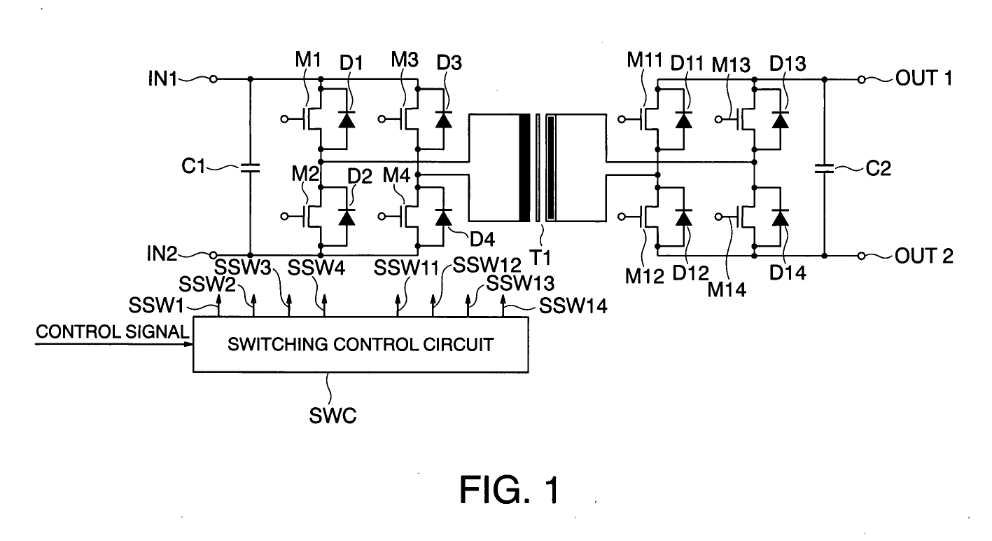

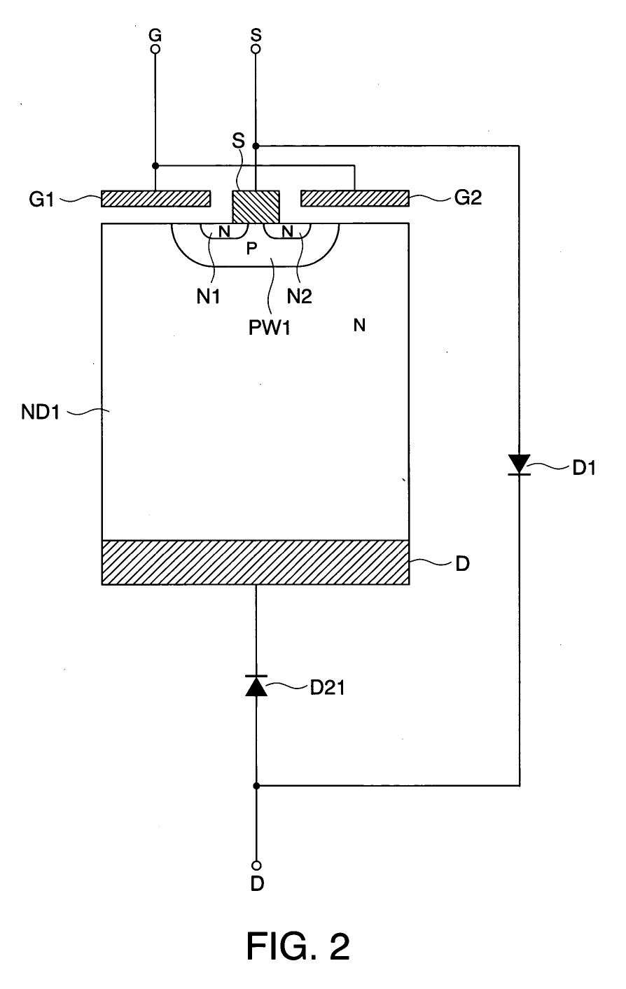

FIG. 1 shows the arrangement of the first embodiment of the present invention, and a MOSFET used in each of the switching elements M1 to M4 and M11 to M14 has an arrangement shown FIG. 2 to prevent a reverse electric current produced by a body diode of the MOSFET.

A P-type base layer (P-type well) PW1 is selectively formed in the surface portion of an N-type drift layer ND1. In the surface portion of the P-type base layer PW1, N-type source layers N1 and N2 are formed with a predetermined spacing between them.

The construction of the MOSFET is symmetrical with respect to the center of the cell, and a plurality of cells are formed regularly in the lateral direction (in the horizontal direction of FIG. 2), or in the lateral and width directions (in the vertical directions against FIG. 2).

On one surface of the N-type drift layer ND1, a source electrode (first main electrode) S is formed to be electrically connected to the N-type source layer N1, P-type base layer PW1, and N-type source layer N2. A source voltage is applied to the source electrode S.

A drain electrode (second main electrode) D is formed to be electrically connected to the other surface of the N-type drift layer ND1. A drain voltage is applied to the drain electrode D.

On one surface of the N-type drift layer ND1, a control electrode G1 is formed via an insulating film (not shown) so as to extend over the N-type source layer N1, P-type base layer PW1, and N-type drift layer ND1. Likewise, a control electrode G2 is formed via an insulating film (not shown) so as to extend over the N-type source layer N2, P-type base layer PW1, and N-type drift layer ND1. A common control voltage is applied to the control electrodes G1 and G2.

Between the drain electrode D and a drain terminal D of this MOSFET, a diode D21 having an anode connected to the drain terminal D and a cathode connected to the drain electrode D is formed. In addition, as is also shown in FIG. 1, the diode D1 is connected by inverse-parallel connection between the drain terminal D and the source electrode S of the MOSFET. That is, the anode is connected to the source electrode S, and the cathode is connected to the drain terminal D.

The diode D1 is a Schottky barrier diode made of, e.g., SiC which uses a semiconductor material having a bandgap of, e.g., 2 V or more. The diode D21 is a Schottky barrier diode, and a barrier height of the Schottky contact between the anode metal and the semiconductor layer is allowed to be lower than that of the general Schottky barrier diode, can be equal to or lower than 0.9 eV, and can be substantially 0.6 eV.

In a normal operation, an electric current flows forward from the drain terminal D to the drain electrode D and source electrode S via the diode D21.

In a reverse-biased state in which the source voltage is higher by a threshold voltage (e.g., about 0.8 V) or more than the drain voltage, an electric current flows from the source electrode S to the drain terminal D via the diode D1.

In addition, the diode D21 blocks an electric current which flows through a body diode formed by the N-type drift layer ND1 and P-type base layer PW1 of the MOSFET. As a consequence, no electric current flows to the body diode parasitic on the MOSFET, so a reverse electric current can be supplied to the Schottky barrier diode D1 capable of high-speed operation. This realizes a high-speed operation in the DC-DC converter using MOSFETs.

In this case, a relationship indicated by
Forward voltage of diode D1<reverse breakdown voltage of diode D21 (1)
is preferable.

When an electric current flows forward in the diode D1, an avalanche electric current flows through the diode D21 if the reverse breakdown voltage of the diode D21 is lower than the forward voltage of the diode D1. As a consequence, an electric current flows from the source to the drain of the MOSFET, i.e., an electric current flows through the body diode of the MOSFET. To avoid this phenomenon, inequality (1) described above is preferable.
Reverse breakdown voltage of diode D21<forward blocking voltage of MOSFET (2)

When the MOSFET is OFF and a voltage is applied from the drain to the source, the forward breakdown voltage of the MOSFET must be higher than the reverse breakdown voltage of the diode D21.
Forward blocking voltage of MOSFET<reverse breakdown voltage of diode D1 (3)

When the MOSFET is OFF and a voltage is applied from the drain to the source, an avalanche electric current flows through the MOSFET if the reverse breakdown voltage of the diode D1 is higher than the forward breakdown voltage of the MOSFET. That is, a sustaining state is allowed to occur in the MOSFET. This is so because the MOSFET has a larger chip area and a lower thermal resistance than those of the diode D1, so the breakdown voltage increases if the heat generated when the avalanche electric current flows is given to the MOSFET. Accordingly, inequality (3) described above desirably holds although it is not essential.

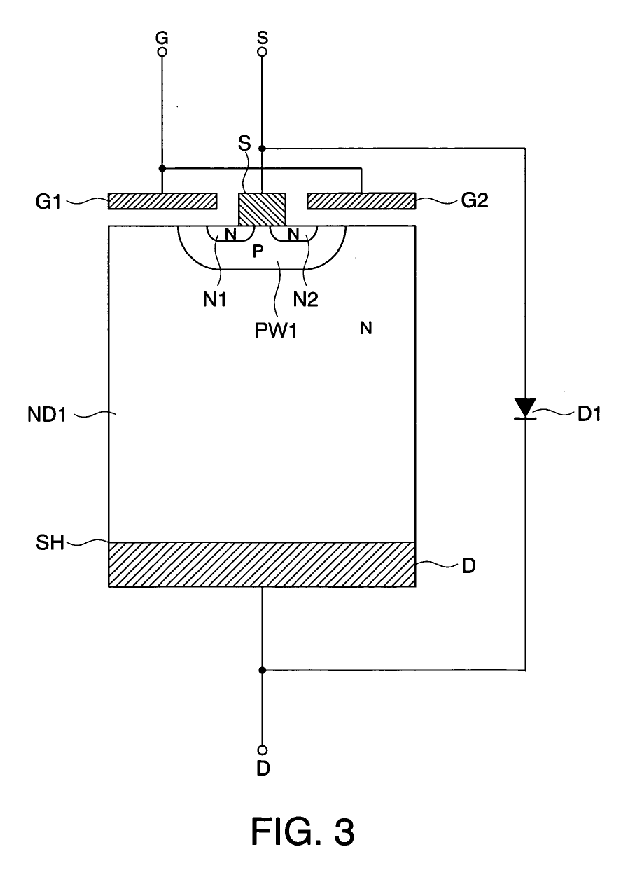

The MOSFET used in the first embodiment may also have an arrangement shown in FIG. 3.

In this MOSFET, a Schottky contact SH is formed in the junction portion between the N-type drift layer ND1 and drain electrode D. Since the Schottky contact SH is formed, a diode in the same direction as the diode D21 shown in FIG. 2 is formed in this junction portion, so a breakdown voltage can be obtained when a reverse bias is applied.

The rest of the arrangement is the same as that shown in FIG. 2 except that the diode D21 which is no longer necessary because the reverse breakdown voltage is obtained is omitted, so an explanation thereof will be omitted.

The reverse breakdown voltage obtained by the Schottky contact need only be higher than the voltage drop when the Schottky barrier diode D1 connected by inverse-parallel connection to the MOSFET is ON, and can be lower than the forward blocking voltage of the MOSFET. For example, this reverse breakdown voltage need only be about 3 V or more.

The operations of the MOSFET shown in FIG. 3 will be explained below.

(1) ON State

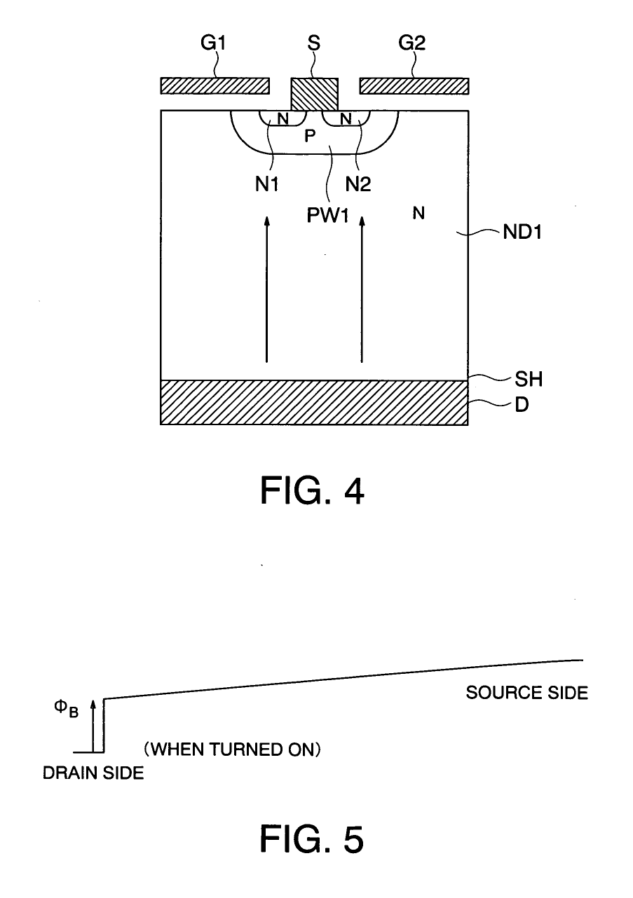

FIG. 4 is a longitudinal sectional view showing the operation of the MOSFET when it is turned on in the forward direction. Also, referring to FIG. 5, the abscissa indicates the direction of depth from the drain to the source, and the ordinate indicates the potential (eV) of the drift layer and Schottky contact SH.

An electric current flows from the drain to the source as indicated by the arrows shown in FIG. 4. Accordingly, electrons flow from the source to the drain, and the voltage drop in the ON state appears in the Schottky contact between the anode metal and the semiconductor layer SH.

A barrier height of the Schottky contact between the anode metal and the semiconductor layer SH is allowed to be lower than that of the general Schottky barrier diode, can be equal to or lower than 0.9 eV, and can be substantially 0.6 eV.

(2) Forward OFF State

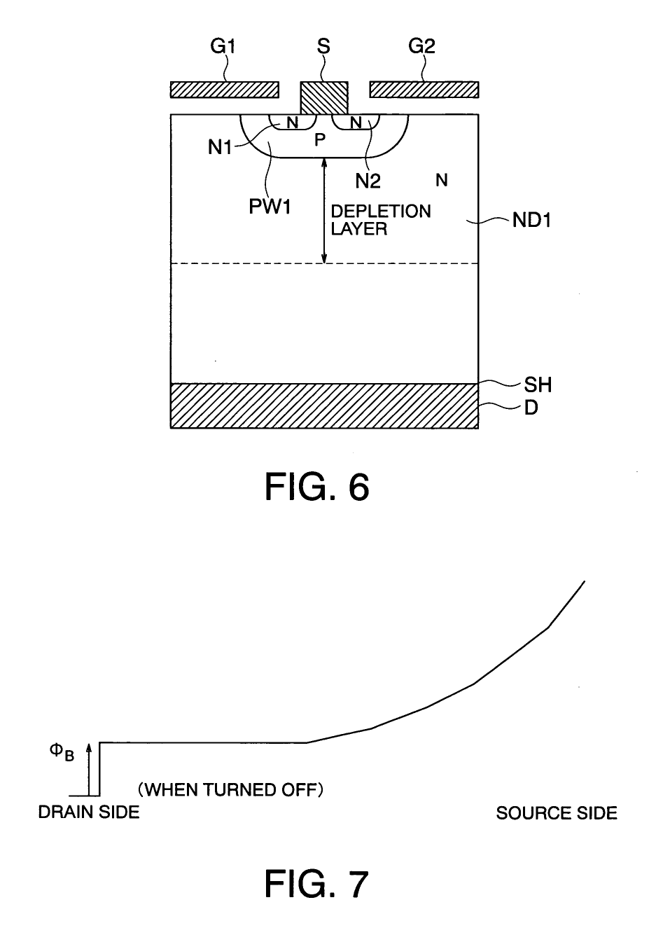

FIG. 6 is a longitudinal sectional view showing the operation when the MOSFET is forward blocking condition. FIG. 7 shows the potential in this case.

As shown in FIG. 6, a portion as a main junction between the P-type base layer PW1 and N-type drift layer ND1 is depleted. This is the same operation state as that of a normal MOSFET, so this state is an OFF state in which no electric current flows.

(3) Reverse Blocking State

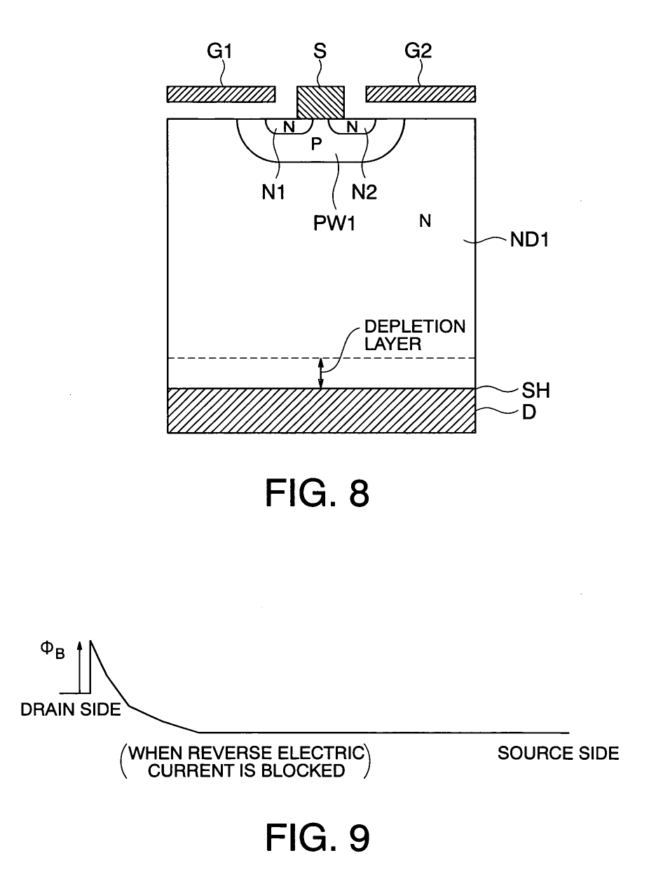

FIG. 8 is a longitudinal sectional view showing the operation when the MOSFET is in a reverse blocking state. FIG. 9 shows the potential in this case.

A region near the Schottky barrier layer SH is depleted, and this blocks an electric current which flows into the drain from the source.

The reverse breakdown voltage of the diode D1 connected by inverse-parallel connection is desirably higher than the forward breakdown voltage of the MOSFET.

This is so because, as described above, if avalanche occurs in a sustaining mode or the like, heat concentrates to the diode because its chip size is smaller than that of the MOSFET, but the degree of concentration of heat in the MOSFET is smaller than that in the diode because the chip size of the MOSFET is larger than that of the diode.

In the conventional MOSFET, as described earlier, when a reverse bias is applied to the drain-to-source path, the body diode formed by the P-type base layer PW1 and N-type drift layer ND1 is forward-biased to perform a bipolar operation, so the operating speed lowers. In this embodiment, an operation like this is inhibited, and the high-speed Schottky barrier diode D1 is connected by inverse-parallel connection to supply a reverse electric current to this portion, thereby achieving a high-speed operation.

Incidentally, a barrier height of the Schottky contact between the anode metal and the semiconductor layer SH is allowed to be lower than that of the general Schottky barrier diode, can be equal to or lower than 0.9 eV, and can be substantially 0.6 eV.

The portion of the Schottky contact between the anode metal and the semiconductor layer SH has a function for turning a current, which is about to flow into a body diode of the MOSFET, toward the Schottky barrier diode D1. Therefore, allowable leak current is not so low, compared with the conventional Schottky barrier diode. Not less than one hundred is sufficient for a ratio of on and off current (a ratio of conductive and leak current).

A voltage drop in the Schottky contact between the anode metal and the semiconductor layer SH can be reduced and loss at on state can be lowered by lowering the barrier height.

The DC-DC converter according to the first embodiment is widely applicable to, e.g., a small-sized loop controller, bidirectional offline power supply, adaptor, and insulated inverter.

FIG. 1 shows the arrangement of the bidirectional DC-DC converter using MOSFETs shown in FIG. 2, and this converter can bidirectionally supply energy between the primary side and secondary side of a transformer T1.

The portion of the Schottky contact between the anode metal and the semiconductor layer SH has a function for turning a current, which is about to flow into a body diode of the MOSFET, toward the Schottky contact between the anode metal and the semiconductor layer.

A capacitance element C1, series-connected switching elements M1 and M2, and series-connected switching elements M3 and M4 are connected in parallel between input terminals IN1 and IN2.

The primary side of the transformer T1 is connected to the connecting point of the switching elements M1 and M2, and to the connecting point of the switching elements M3 and M4.

A capacitance element C2, series-connected switching elements M11 and M12, and series-connected switching elements M13 and M14 are connected in parallel between output terminals OUT1 and OUT2.

The secondary side of the transformer T1 is connected to the connecting point of the switching elements M11 and M12, and to the connecting point of the switching elements M13 and M14.

In addition, diodes D1 to D4 are connected in parallel between the drains and sources of the switching elements M1 to M4, and diodes D11 to D14 are connected in parallel between the drains and sources of the switching elements M11 to M14. The diode D1, for example, has an anode connected to the connecting point of the switching elements M1 and M2, and a cathode connected to the input terminal IN1.

This circuit has a bridge configuration; an electric current flows in one way when the switching elements M1 and M4 are turned on and the switching elements M2 and M3 are turned off, and flows in the other way when the switching elements M2 and M3 are turned on and the switching elements M1 and M4 are turned off.

A switching control circuit SWC controls the ON/OFF operations of the switching elements M1 to M4 and M11 to M14. The switching control circuit SWC receives a control signal from a central control unit (not shown) or the like, and generates and supplies switching control signals SSW1 to SSW4 and SSW11 to SSW14 to the switching elements M1 to M4 and M11 to M14.

The MOSFETs used for the switching elements M1 to M4 and M11 to M14 has a configuration shown in FIG. 2 to prevent a reverse electric current caused by the body diode.

### Second Embodiment

A semiconductor device according to the second embodiment of the present invention will be described below. The circuit configuration of the entire device is the same as that shown in FIG. 1, and an explanation thereof will be omitted.

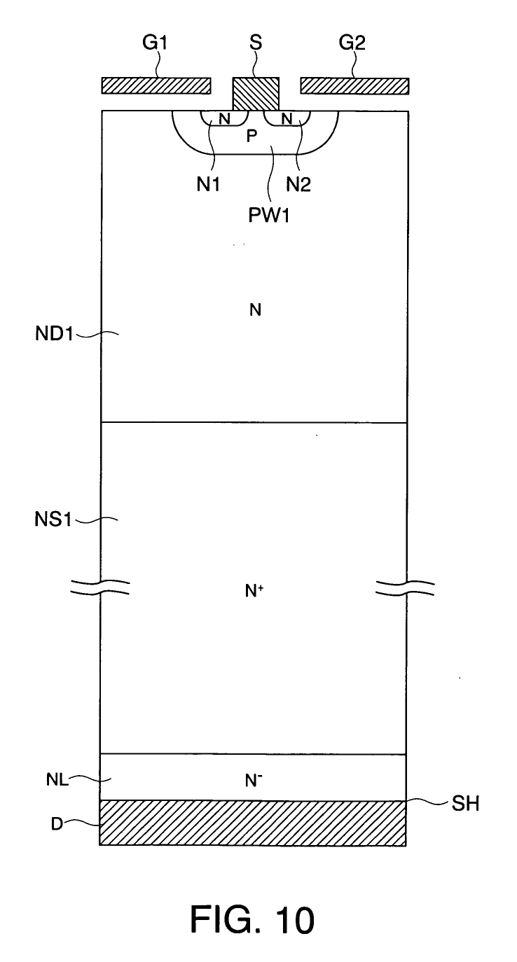

The second embodiment differs from the first embodiment in the arrangement of a MOSFET, and FIG. 10 shows the longitudinal sectional structure of the MOSFET.

In the first embodiment as shown in FIGS. 2 and 3, the drain electrode D is formed on the surface of the N-type drift layer ND1. In the second embodiment, however, an N-type drift layer ND1 is formed on one surface of an N⁺-type semiconductor substrate NS1, an N⁻-type lightly doped layer (e.g., the impurity concentration is 1×10¹⁷/cm³ or less) NL is formed on the other surface, and a drain electrode D is formed on the surface of the N⁻-type lightly doped layer NL. A Schottky contact SH is formed between the N⁻-type lightly doped layer NL and drain electrode D. To form the Schottky contact SH, the N⁻-type lightly doped layer NL is desirably formed as described above.

When this MOSFET is to be used as a switching element, the anode and cathode of a diode D1 are connected to a source electrode S and the drain electrode D, respectively, as shown in FIGS. 1 and 3, so electric current is commutated to the anti-parallel diode D1 without through the body diode when a reverse bias is applied.

The same effects as in the first embodiment can be obtained even when the N-type drift layer ND1 is formed on the surface of the N⁺-type semiconductor substrate NS1 as described above.

Further, in the first embodiment, a thin wafer made of only an N⁻-type layer is required. Therefore, it is difficult to be manufactured because there is a problem of a warp in a wafer, or the like.

By contrast, according to the present second embodiment, it is possible to manufacture the device using a thick wafer by increasing the thickness of the N⁺-type layer. As a result, the device can be manufactured easily.

### Third Embodiment

A semiconductor device according to the third embodiment of the present invention will be described below. The circuit configuration of the entire device is the same as that shown in FIG. 1, and an explanation thereof will be omitted.

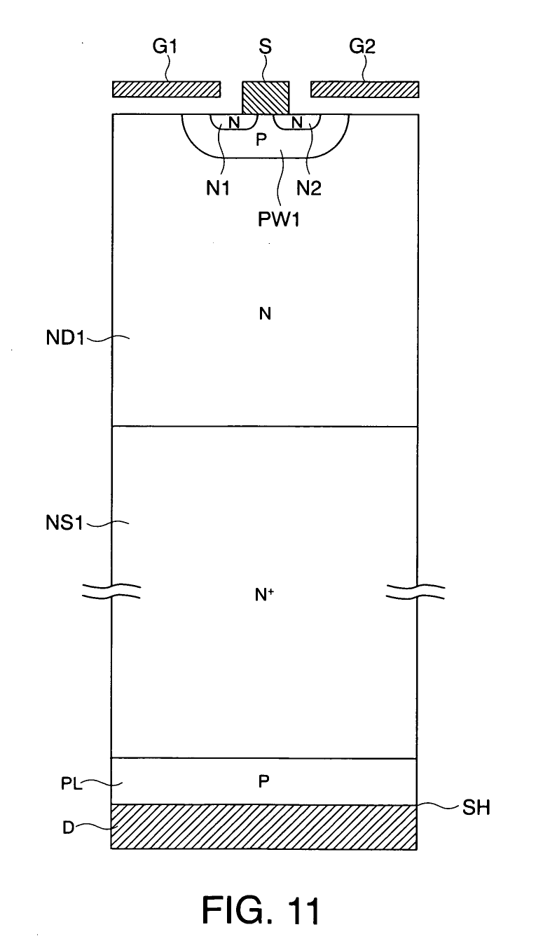

The third embodiment uses a MOSFET having a longitudinal sectional structure shown in FIG. 11.

In the third embodiment, an N-type drift layer ND1 is formed on one surface of an N⁺-type semiconductor substrate NS1, a P-type impurity diffusion layer PL is formed on the other surface, and a drain electrode D is formed on the surface of the P-type impurity diffusion layer PL.

The P-type impurity layer PL and the N⁺-type semiconductor substrate NS1 form a P-N junction, so that the junction forms a diode in the same direction as D21 shown in FIG. 2.

Also, when the P-type impurity diffusion layer PL is formed, holes flow into the N⁺-type semiconductor substrate NS1. However, in the N⁺-type semiconductor substrate NS1, these holes recombine with electrons and disappear because the length of the N⁺-type semiconductor substrate NS1 is much longer than the hole diffusion length in the N⁺-type semiconductor substrate NS1. For example, the length of NS1 is 80 μm, or larger than the thickness of the drift layer.

When this MOSFET is to be used as a switching element, the anode and cathode of a diode D1 are connected to a source electrode S and the drain electrode D, respectively, as shown in FIGS. 1 and 3, so that electric current is commutated to the anti-parallet diode D1 without through the body diode when a reverse bias is applied.

The same effects as in the first and second embodiments can be obtained even when the N-type drift layer ND1 is formed on one surface of the N⁺-type semiconductor substrate NS1 and the P-type impurity layer PL is formed on the other surface as described above.

Incidentally, an epitaxial layer can be used instead of the P-type impurity layer PL. An impurity concentration can be reduced, so that injection of holes is suppressed. As a result, high speed of operation can be achieved.

Furthermore, a metal junction of a reverse side (drain) of the wafer can be ohmic contact, thus the conventional manufacturing process can be used. In addition, the property of the device is stable because P-N junction is used.

### Fourth Embodiment

A semiconductor device according to the fourth embodiment of the present invention will be described below. The circuit configuration of the entire device is the same as that shown in FIG. 1, and an explanation thereof will be omitted.

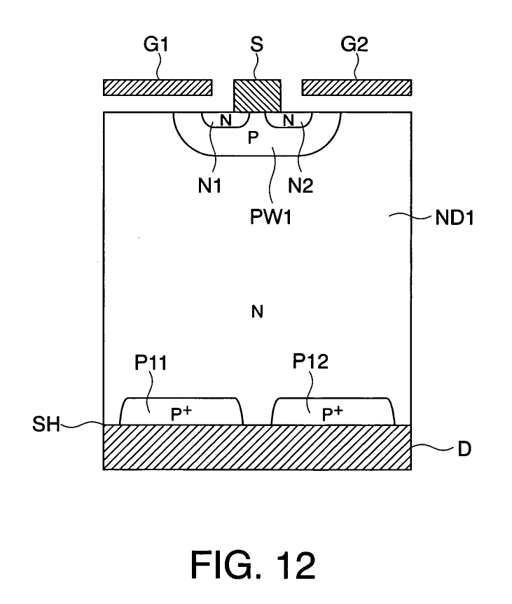

The fourth embodiment uses a MOSFET having a longitudinal sectional structure shown in FIG. 12. P⁺-type impurity diffusion layers P11 and P12 are formed in the surface portion, in which a drain electrode D is formed, of an N-type drift layer ND1. A Schottky contact SH is formed between the N-type drift layer ND1 and drain electrode D.

The fourth embodiment differs from the third embodiment in that the N-type drift layer ND1 is not formed on an N⁺-type semiconductor substrate NS1 having a sufficient length. Therefore, to prevent many holes from flowing into the N-type drift layer ND1 from the P⁺-type impurity diffusion layers P11 and P12, these diffusion layers are not formed as continuous layers but divided into a plurality of portions.

A diode is formed in a direction in which it blocks an electric current which flows into the body diode between the P⁺-type impurity diffusion layers P11 and P12 and the N-type drift layer ND1 in the fourth embodiment as well.

In the fourth embodiment, as in the first to third embodiments described above, no electric current flows into the body diode even when a reverse bias is applied, so a high-speed operation can be realized. The Schottky metal can be platinum, gold, titanium, or tungsten, and may also be aluminum if the concentration in the interface is 1×10¹⁷/cm³ or less.

A package structure when the semiconductor device according to any of the first to fourth embodiments is to be packaged will be explained below.

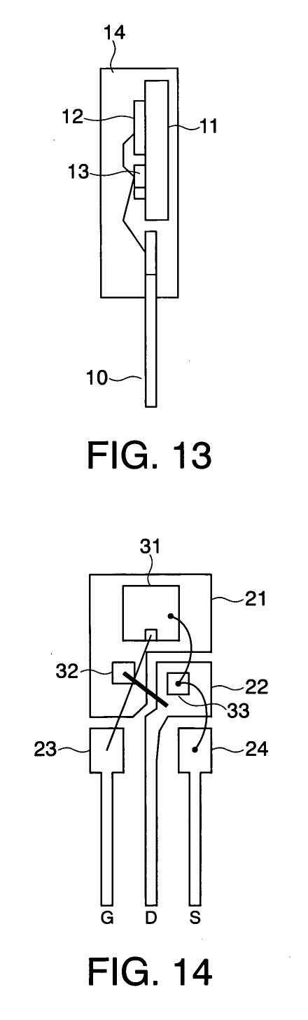

FIG. 13 shows an example of the longitudinal sectional structure of the package. A chip 12 of a MOSFET and a chip 13 of at least one diode are mounted on a bed 11 of a lead frame. The chips 12 and 13 and a lead 10 are connected by bonding wires, and the entire package is encapsulated with molding resin 14.

Examples of the planar structure of this package are shown in FIGS. 14, 15, and 16.

The planar structure shown in FIG. 14 is equivalent to the structure using the two diodes D1 and D21 as shown in FIG. 2 of the first embodiment.

A chip 31 of the MOSFET and a chip 32 of the diode D21 are mounted on a bed 21, and a chip 33 of the diode D1 is mounted on a lead 22 connected to a drain electrode D. A lead 23 is connected to a control electrode G, and a lead 24 is connected to a source electrode S. The source electrode S of the chip 31 of the MOSFET is connected to the lead 24 by a bonding wire. The control electrode G is connected to the lead 23 by a bonding wire. The anode of the diode D21 which is mounted such that its cathode is in contact with the bed 21 is connected to the lead 22 by a bonding wire. The anode of a diode D33 which is mounted such that its cathode is in contact with the lead 22 is connected to the lead 24 by a bonding wire. The entire package is encapsulated with molding resin (not shown).

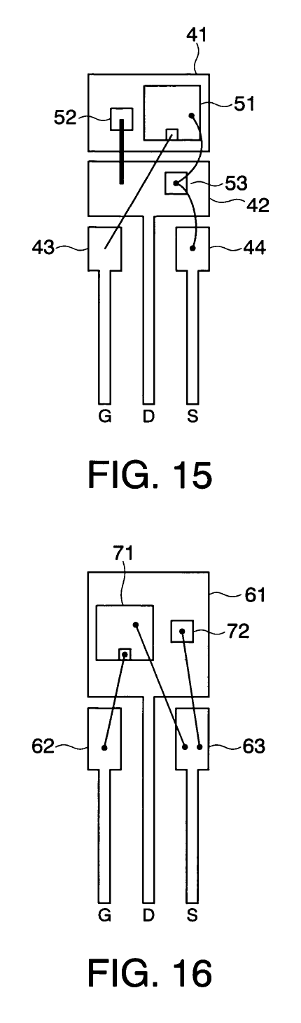

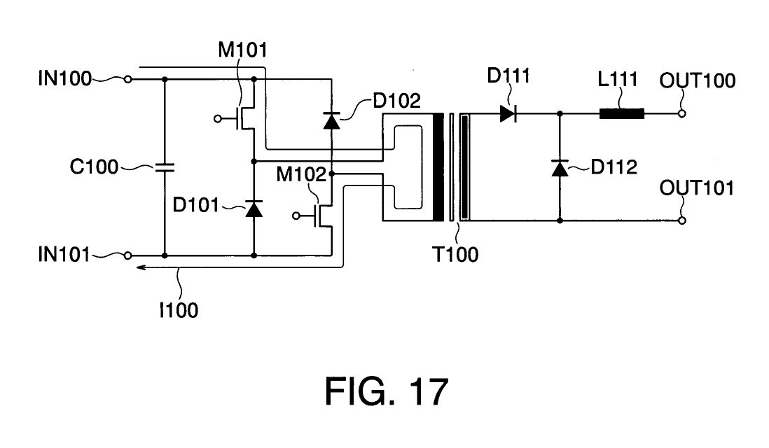

The planar structure shown in FIG. 15 is also equivalent to the structure using the two diodes D1 and D21 shown in FIG. 2.

A chip 51 of the MOSFET and a chip 52 of the diode D21 are mounted on a bed 41, and a chip 53 of the diode D21 is mounted on a lead 42 connected to a drain electrode D. A lead 43 is connected to a control electrode G, and a lead 44 is connected to a source electrode S. The individual electrodes are connected to the leads 42 to 44 by bonding wires. The entire package is encapsulated with molding resin (not shown).

Compared to the package structure shown in FIG. 14, the package structure shown in FIG. 15 simplifies the shapes and arrangements of the bed 41 and leads 42 to 44, and facilitates the manufacture of the metal mold of the lead frame.

The planar structure shown in FIG. 16 is equivalent to the structure using the diode D1 as shown in FIG. 3 of the first embodiment.

A chip 71 of the MOSFET and a chip 72 of the diode D1 are mounted on a bed 61 integrated with a lead connected to a drain electrode D. A lead 62 is connected to a control electrode G, and a lead 63 is connected to a source electrode S. The individual electrodes are connected to the leads 62 and 63 by bonding wires. The entire package is encapsulated with molding resin (not shown).

This package structure makes the number of parts smaller and the manufacture of the lead frame metal mold easier than those of the package structure shown in FIG. 15.

In this structure, therefore, the parasitic capacitance between the chip 71 of the MOSFET and the chip 72 of the diode can be greatly reduced by mounting them on the bed 61 of the same lead frame and encapsulating them with the same molding resin.

In the semiconductor devices according to the above embodiments, in each of the MOSFETs used as the first to eighth switching elements, a Schottky contact is formed between the first-conductivity-type semiconductor layer and second main electrode. When a reverse bias is applied, therefore, an electric current flows not to the body diode but to the first to eighth diodes connected by inverse-parallel connection. This realizes a high-speed operation.

Each of the above embodiments is merely an example, and hence does not limit the present invention. Accordingly, these embodiments can be variously modified within the technical scope of the invention. For example, the upper construction of the MOSFET may have a trench gate.

What is claimed is:

1. A semiconductor device including a MOSFET, said MOSFET comprising:
a second-conductivity-type semiconductor layer selectively formed in one surface portion of a first first-conductivity-type semiconductor layer;
a second first-conductivity-type semiconductor layer selectively formed in a surface portion of said second-conductivity-type semiconductor layer;
a first main electrode electrically connected to said second first-conductivity-type semiconductor layer and second-conductivity-type semiconductor layer;
a second main electrode electrically connected to the other surface of said first first-conductivity-type semiconductor layer; and
a control electrode formed on the surfaces of said second first-conductivity-type semiconductor layer, second-conductivity-type semiconductor layer, and first first-conductivity-type semiconductor layer via an insulating film, and
a junction between said second main electrode and first first-conductivity-type semiconductor layer is a Schottky contact.

2. A semiconductor device including a MOSFET, said MOSFET comprising:
a first second-conductivity-type semiconductor layer selectively formed in one surface portion of a first first-conductivity-type semiconductor layer formed in one surface portion of a first-conductivity-type semiconductor substrate;
a second first-conductivity-type semiconductor layer formed selectively in a surface portion of said second-conductivity-type semiconductor layer;
a first main electrode electrically connected to said second first-conductivity-type semiconductor layer and first second-conductivity-type semiconductor layer;
a third first-conductivity-type semiconductor layer or second second-conductivity-type semiconductor layer formed in the other surface portion of said first-conductivity-type semiconductor substrate, and having an impurity concentration lower than that of said first-conductivity-type semiconductor substrate;
a second main electrode electrically connected to said third first-conductivity-type semiconductor layer or second second-conductivity-type semiconductor layer; and
a control electrode formed on the surfaces of said second first-conductivity-type semiconductor layer, first second-conductivity-type semiconductor layer, and first first-conductivity-type semiconductor layer via an insulating film, and
a junction between said second main electrode and said third first-conductivity-type semiconductor layer or second second-conductivity-type semiconductor layer is a Schottky junction contact.

3. A semiconductor device including a MOSFET, said MOSFET further comprising:
a second second-conductivity-type semiconductor layer selectively formed in the other surface portion of said first first-conductivity-type semiconductor layer;
wherein a second main electrode is electrically connected to the other surface of said first first-conductivity-type semiconductor layer and said second second-conductivity-type semiconductor layer; and
a control electrode is formed on the surfaces of said second first-conductivity-type semiconductor layer, first second-conductivity-type semiconductor layer, and first first-conductivity-type semiconductor layer via an insulating film.

4. A semiconductor device comprising:
a MOSFET having,
a second-conductivity-type semiconductor layer selectively formed in one surface portion of a first first-conductivity-type semiconductor layer,
a second first-conductivity-type semiconductor layer selectively formed in a surface portion of said second-conductivity-type semiconductor layer,
a first main electrode electrically connected to said second first-conductivity-type semiconductor layer and second-conductivity-type semiconductor layer, and connected to a source terminal,
a second main electrode electrically connected to the other surface of said first first-conductivity-type semiconductor layer, and
a control electrode formed on the surfaces of said second first-conductivity-type semiconductor layer, second-conductivity-type semiconductor layer, and first first-conductivity-type semiconductor layer via an insulating film; and
a diode having a cathode connected to said second main electrode, and an anode connected to a drain terminal.

5. A device according to claim 1, further comprising:
a bridge circuit having
a first capacitance element connected in series between first and second input terminals, and
first and second switching elements connected in series between said first and second input terminals, said first and second switching elements respectively consisted of said MOSFET.

6. A device according to claim 2, further comprising:
a bridge circuit having
a first capacitance element connected in series between first and second input terminals, and
first and second switching elements connected in series between said first and second input terminals, said first and second switching elements respectively consisted of said MOSFET.

7. A device according to claim 3, further comprising:
a bridge circuit having
a first capacitance element connected in series between first and second input terminals, and
first and second switching elements connected in series between said first and second input terminals, said first and second switching elements respectively consisted of said MOSFET.

8. A device according to claim 4, further comprising:
a bridge circuit having
a first capacitance element connected in series between first and second input terminals, and
first and second switching elements connected in series between said first and second input terminals, said first and second switching elements respectively consisted of said MOSFET.

9. A device according to claim 1, said device further comprising, a Schottky barrier diode having an anode connected to said first main electrode of said MOSFET, and a cathode connected to said second main electrode of said MOSFET.

10. A device according to claim 2, said device further comprising, a Schottky barrier diode having an anode connected to said first main electrode of said MOSFET, and a cathode connected to said second main electrode of said MOSFET.

11. A device according to claim 3, said device further comprising, a Schottky barrier diode having an anode connected to said first main electrode of said MOSFET, and a cathode connected to said second main electrode of said MOSFET.

12. A device according to claim 4, said device further comprising, a Schottky barrier diode having an anode connected to said first main electrode of said MOSFET, and a cathode connected to said drain terminal.

13. A device according to claim 1, wherein said MOSFET and a diode connected in parallel to said MOSFET are mounted on the same lead frame in the same package.

14. A device according to claim 2, wherein said MOSFET and a diode connected in parallel to said MOSFET are mounted on the same lead frame in the same package.

15. A device according to claim 3, wherein said MOSFET and a diode connected in parallel to said MOSFET are mounted on the same lead frame in the same package.

16. A device according to claim 4, wherein said MOSFET and a diode connected in parallel to said MOSFET are mounted on the same lead frame in the same package.

17. A device according to claim 1, wherein a barrier height of the Schottky contact is equal to or lower than 0.9 eV.

18. A device according to claim 2, wherein a barrier height of the Schottky contact is equal to or lower than 0.9 eV.

19. A device according to claim 3, wherein a barrier height of the Schottky contact is equal to or lower than 0.9 eV.

20. A device according to claim 4, wherein a barrier height of the Schottky contact is equal to or lower than 0.9 eV.
